(19) United States
(12) Patent Application Publication
(10) Pub. No.: US 2020/0127140 A1
(43) Pub. Date: Apr. 23, 2020

(54) ARRAY SUBSTRATE, MANUFACTURING METHOD FOR SAME, AND DISPLAY PANEL

(71) Applicant: Wuhan China Star Optoelectronics Semiconductor Display Technology Co., Ltd., Wuhan (CN)

(72) Inventor: Caiqin CHEN, Wuhan (CN)

(73) Assignee: Wuhan China Star Optoelectronics Semiconductor Display Technology Co., Ltd., Wuhan (CN)

(21) Appl. No.: 16/325,394

(22) PCT Filed: Oct. 9, 2018
(86) PCT No.: PCT/CN2018/109452

§ 371 Date: Feb. 14, 2019

(30) Foreign Application Priority Data
Sep. 18, 2018 (CN) 201811084408.6

(51) Int. Cl. H01L 29/786; H01L 51/56; H01L 51/00; H01L 27/32; H01L 27/12

(52) U.S. Cl. CPC H01L 29/78621; H01L 51/56; H01L 51/0011; H01L 2029/7863; H01L 27/127; H01L 2227/323; H01L 27/3258

(57) ABSTRACT

An array substrate, a manufacturing method for same, and a display panel are provided. In the manufacturing method, ion doping is performed once on an active layer, and the doped active layer forms a first doped region and a second doped region through a predetermined process. On the basis of a current process and without increasing the quantity of masks, a PMOS LDD structure is added to an AMOLED. This effectively reduces a period of a panel array manufacturing process and reduces manufacturing costs.

### FIELD OF INVENTION

The present disclosure relates to the display field, and in particular, to an array substrate, a manufacturing method for same, and a display panel.

### BACKGROUND OF INVENTION

Low temperature poly-silicon (LTPS) has a high electron mobility, which may effectively reduce the area of a device of a thin film transistor (TFT), then improve a pixel aperture ratio, and may reduce entire power consumption while increasing panel display luminance, so that manufacturing costs of a panel are greatly reduced. Therefore, LTPS has currently become a hot technology in the field of liquid crystal display (LCD).

In a conventional LTPS LCD, a complementary metal oxide semiconductor (CMOS) device is often configured to form a basic unit of a panel drive circuit. To balance device characteristics of an n-type metal oxide semiconductor (NMOS) and a p-type metal oxide semiconductor (PMOS), only a lightly doped drain (Lightly Doped Drain, LDD) structure is usually manufactured in an NMOS device. In the prior art, a PMOS structure is usually used for an active-matrix organic light-emitting diode (AMOLED), a PMOS device structure for compensating for Vth is used for a pixel. The structures are complex and have a higher requirement on a leakage current. Therefore, if a PMOS LDD structure can be added on the basis of reducing structural complexity, optical performance of the AMOLED is greatly improved.

However, an LTPS process is complex, and in an array process, there are a relatively large quantity of layers of formed films of a substrate array, and a relatively large quantity of masks are required. Moreover, addition of the PMOS LDD structure to the AMOLED causes an increase in the quantity of masks. Consequently, a manufacturing capacity time of a product is increased, leading to increased illumination costs and operating costs.

### SUMMARY OF INVENTION

The present disclosure provides an array substrate, a manufacturing method for same, and a display panel, so as to resolve a technical problem that a process of adding a PMOS LDD structure to an AMOLED is complex.

To resolve the foregoing problem, technical solutions provided in the present disclosure are as follows:

The present disclosure provides a manufacturing method for an array substrate. The method includes steps of:

S101: providing a substrate;
S102: forming a buffer layer, an active layer, a first insulation layer, a first metal layer, a second insulation layer, a second metal layer, and a third insulation layer sequentially on the substrate, where an area of the second metal layer is greater than an area of the first metal layer;
S103: performing ion doping on a part of the active layer, so that the part of the active layer forms a first doped region, and treating the first doped region using a predetermined process, so that the part of the active layer forms a second doped region; and
S104: forming a source and a drain on the third insulation layer.

In the manufacturing method of the present disclosure, S103 includes steps of:

S10311: performing ion doping on the part of the active layer by using the second metal layer and the first metal layer as blocking layers, so that the part of the active layer forms the first doped region; and
S10312: treating the first doped region by using the predetermined process, so that some ions of the first doped region diffuse in all directions from the first doped region, and the part of the active layer forms the second doped region,
where an ion concentration of the first doped region is greater than an ion concentration of the second doped region.

In the manufacturing method of the present disclosure, the second doped region surrounds the first doped region.

In the manufacturing method of the present disclosure, the area of the second doped region is greater than or equal to a difference between the area of the second metal layer and the area of the first metal layer.

According to a preferred embodiment of the present disclosure, S103 includes steps of:

S10321: forming a via on the third insulation layer, where the via passes through the third insulation layer, the second insulation layer, and a part of the first insulation layer, so that the part of the active layer is exposed at the via;
S10322: performing ion doping on the exposed part of the active layer, so that the part of the active layer forms the first doped region; and
S10323: treating the first doped region by using the predetermined process, so that some ions of the first doped region diffuse in all directions from the first doped region, and the part of the active layer forms the second doped region.

In the manufacturing method of the present disclosure, the first doped region has a shape same as a shape of the via, and the shape of the first doped region is a polygon or a circle.

In the manufacturing method of the present disclosure, the forming the first doped region and the second doped region includes steps of:

performing first time of ion doping on the part of the active layer by using the first metal layer as a blocking layer, so that the part of the active layer forms the second doped region; and performing second time of ion doping on the part of the active layer by using the second metal layer as a blocking layer, so that the part of the active layer forms the first doped region.

In the manufacturing method of the present disclosure, the performing second time of ion doping on the part of the active layer by using the second metal layer as a blocking layer further includes a step of:

performing second time of ion doping on the part of the active layer by using the second metal layer and a photoresist enabling the second metal layer to be patterned, the second metal layer and the patterned second insulation layer, as well as the second metal layer, the photoresist enabling the second metal layer to be patterned and the patterned second insulation as blocking layers, so that the part of the active layer forms the first doped region.

The present disclosure further provides an array substrate, including a substrate, an active layer located on the substrate, a first metal layer located on the active layer, and a second metal layer located on the first metal layer,

where the active layer includes a first doped region disposed inside the active layer and a second doped region disposed outside the active layer, and the area of the second doped region is greater than or equal to a difference between the area of the second metal layer and the area of the first metal layer.

In the array substrate of the present disclosure, the area of the second metal layer is greater than the area of the first metal layer.

In the array substrate of the present disclosure, the array substrate further includes at least two vias and a source and drain layer; and the source and drain layer is electrically connected to the second doped region through the vias.

In the array substrate of the present disclosure, the first doped region has a shape same as a shape of the via. The shape of the first doped region is a polygon or a circle.

In the array substrate of the present disclosure, the second doped region surrounds the first doped region.

In the array substrate of the present disclosure, the ion concentration of the first doped region is greater than the ion concentration of the second doped region.

The present disclosure further provides a display panel, where the display panel includes an array substrate, and the array substrate includes a substrate, an active layer located on the substrate, a first metal layer located on the active layer, and a second metal layer located on the first metal layer,

where the active layer includes a first doped region disposed inside the active layer and a second doped region disposed outside the active layer, and the area of the second doped region is greater than or equal to a difference between the area of the second metal layer and the area of the first metal layer.

In the display panel of the present disclosure, the area of the second metal layer is greater than the area of the first metal layer.

In the display panel of the present disclosure, the array substrate further includes at least two vias and a source and drain layer; and

the source and drain layer is electrically connected to the second doped region through the vias.

In the display panel of the present disclosure, the first doped region has a shape same as a shape of the via, and the shape of the first doped region is a polygon or a circle.

In the display panel of the present disclosure, the second doped region surrounds the first doped region.

In the display panel of the present disclosure, the ion concentration of the first doped region is greater than the ion concentration of the second doped region.

Beneficial effects are as follows: In the present disclosure, ion doping is performed once on the active layer, and the doped active layer forms the first doped region and the second doped region using a predetermined process. In the present disclosure, on the basis of the current process and without increasing the quantity of masks, a PMOS LDD structure is added to an AMOLED. This effectively reduces a period of a panel array manufacturing process and reduces manufacturing costs.

### BRIEF DESCRIPTION OF DRAWINGS

In order to illustrate the technical solutions in the embodiments or in the prior art more clearly, the accompanying drawings required in descriptions of the embodiments or in the prior art are briefly described in the following. Obviously, the drawings in the following description are only partial embodiments of the present disclosure, and those of ordinary skill in the art can obtain other drawings according to the drawings without any creative work.

FIG. 1 is a diagram of steps of a manufacturing method for an array substrate according to Embodiment 1 of the present disclosure;

FIG. 2A to FIG. 2K are flowcharts of a manufacturing method for an array substrate according to Embodiment 1 of the present disclosure;

FIG. 3 is a first top view of an array substrate according to Embodiment 1 of the present disclosure;

FIG. 4 is a second top view of an array substrate according to Embodiment 1 of the present disclosure;

FIG. 5 is a diagram of steps of a manufacturing method for an array substrate according to Embodiment 2 of the present disclosure;

FIG. 6A to FIG. 6J are flowcharts of a manufacturing method for an array substrate according to Embodiment 2 of the present disclosure;

FIG. 7 is a diagram of a first film layer structure of an array substrate according to Embodiment 3 of the present disclosure; and

FIG. 8 is a diagram of a second film layer structure of an array substrate according to Embodiment 3 of the present disclosure.

### DETAILED DESCRIPTION OF PREFERRED EMBODIMENTS

The following embodiments are described with reference to the accompanying drawings, and are used to exemplify particular embodiments that the present disclosure can be used to implement. Direction terms mentioned in the present disclosure such as “upper”, “lower”, “front”, “rear”, “left”, “right”, “inner”, “outer”, and “side” are only directions with reference to the accompanying drawings. Therefore, the used direction terms are intended to describe and understand the present disclosure, but are not intended to limit the present disclosure. In the drawings, units whose structures are the same are indicated by using the same reference numbers.

### Embodiment 1

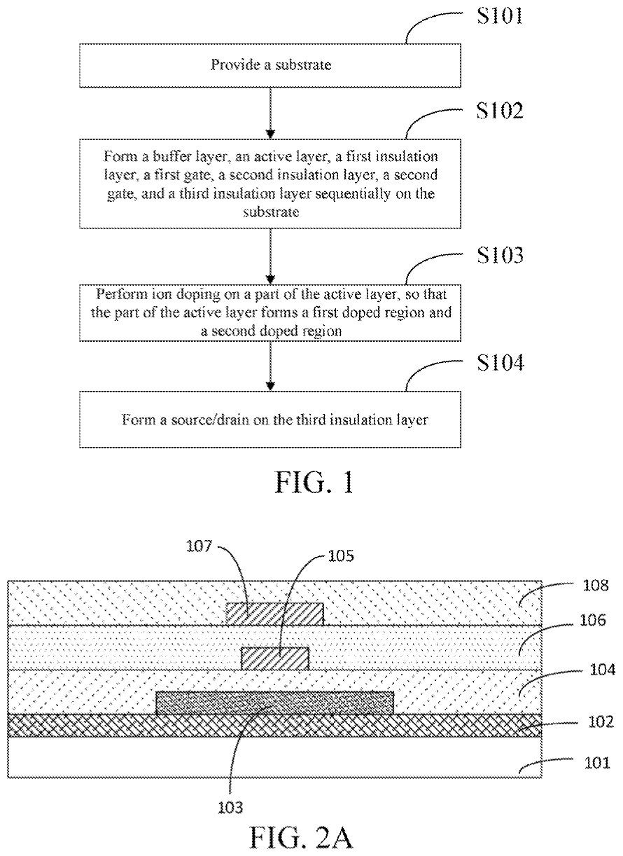

FIG. 1 is a diagram of steps of a manufacturing method for an array substrate according to Embodiment 1 of the present disclosure. The manufacturing method includes the following steps.

S101: Provide a substrate 101.

The substrate 101 is provided, and the substrate 101 may be one of a glass substrate, a quartz substrate, a resin substrate, and the like.

S102: Form a buffer layer 102, an active layer 103, a first insulation layer 104, a first metal layer 105, a second insulation layer 106, a second metal layer 107, and a third insulation layer 108 sequentially on the substrate 101.

In an embodiment, an area of the second metal layer 107 is greater than an area of the first metal layer 105.

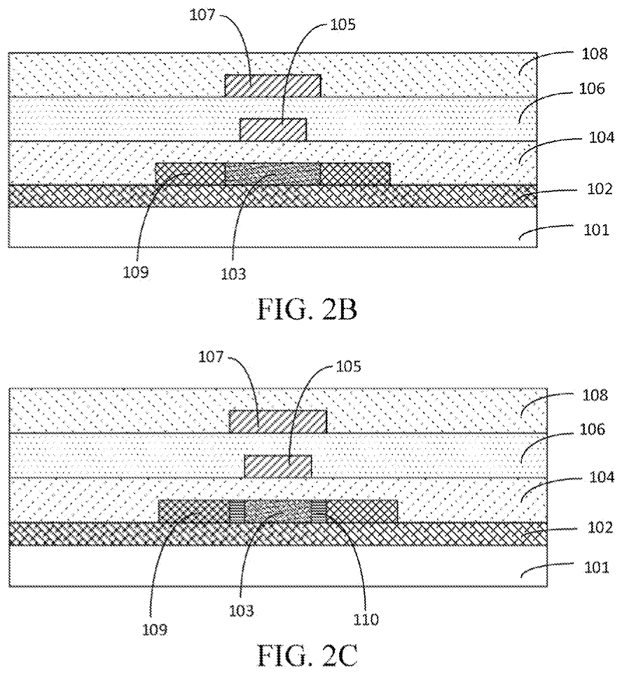

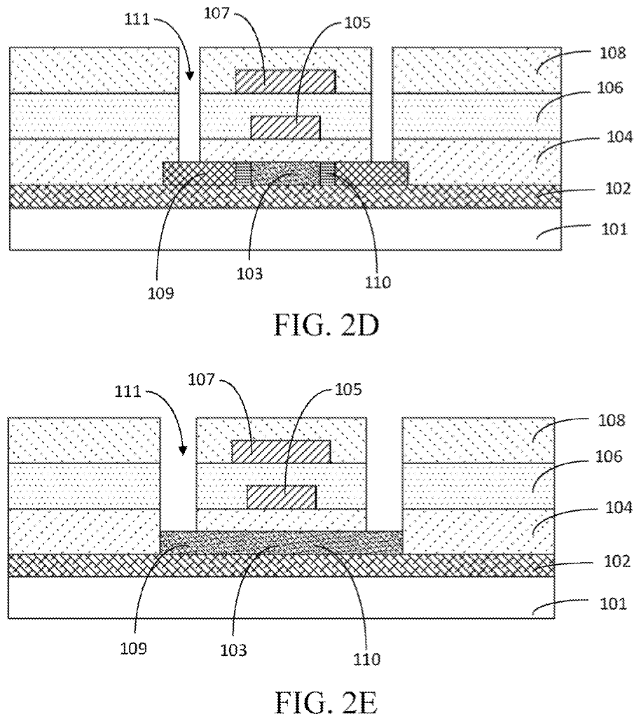

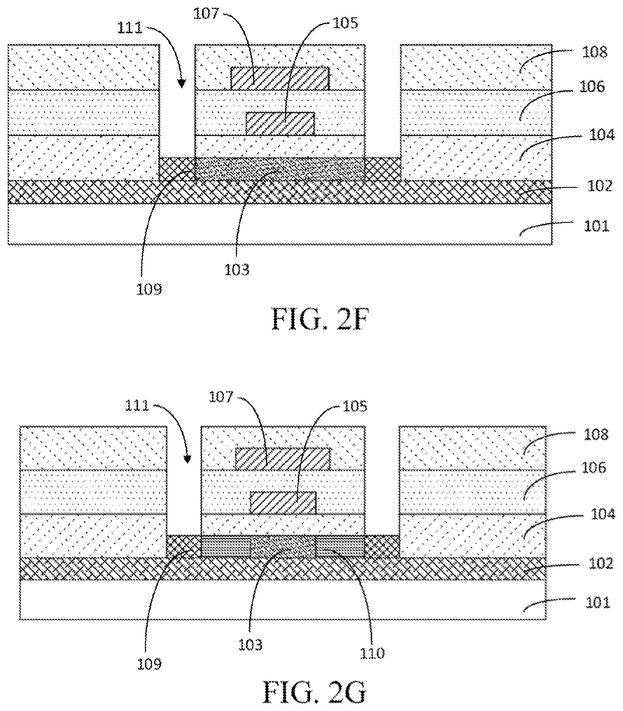

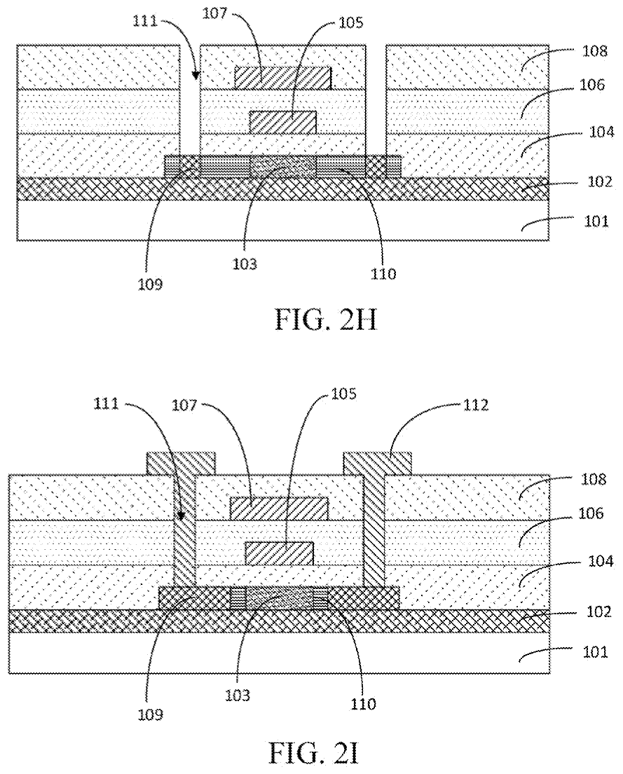

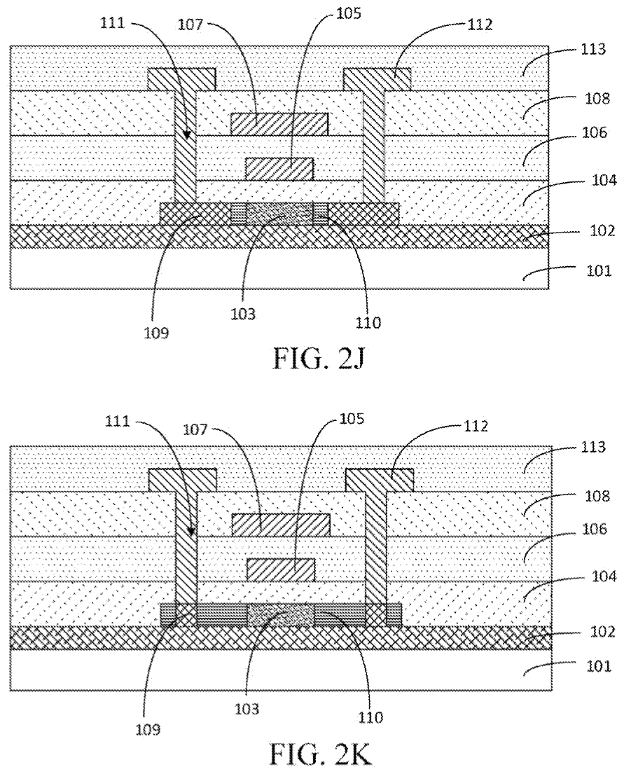

FIG. 2A to FIG. 2K are flowcharts of a manufacturing method for an array substrate according to Embodiment 1 of the present disclosure.

Referring to FIG. 2A, step S102 specifically includes the following steps.

S1021: Form the buffer layer 102 on the substrate 101.

S1022: Form the active layer 103 on the buffer layer.

In this step, firstly, an active layer thin film is formed on the buffer layer, where the active layer thin film is formed by poly-silicon. Secondly, a first mask manufacturing process is used for the active layer thin film, and after a first photoresist layer (not drawn) is formed on the active layer thin film, exposed using a mask plate (not drawn), developed, and treated using a first etching patterning process, the active layer thin film forms a pattern of the active layer 103 shown in FIG. 2B, and the first photoresist layer is stripped.

S1023: Form the first insulation layer 104 on the active layer 103.

The first insulation layer 104 is formed on the active layer 103.

In an embodiment, the first insulation layer 104 is a first gate insulation layer, and the first gate insulation layer covers the active layer 103. The first gate insulation layer is mainly configured to isolate the active layer 103 from other metal layers.

S1024: Form the first metal layer 105 on the first insulation layer 104.

A metal layer is formed on the first insulation layer 104. The metal layer may be usually made of a metal such as molybdenum, aluminum, aluminum nickel alloy, molybdenum tungsten alloy, chromium, or copper, or may be a composition of several of the foregoing metal materials.

In an embodiment, the first metal layer 105 may be made of molybdenum.

A second mask manufacturing process is used for the first metal layer, and after a second photoresist layer is formed on the first metal layer, exposed using a mask plate (not drawn), developed, and treated using a second etching patterning process, the first metal layer forms the first metal layer 105 shown in FIG. 2A, and the second photoresist layer is stripped.

In an embodiment, the first metal layer 105 is a gate of the array substrate.

S1025: Form a second insulation layer 106 on the first metal layer 105.

In this step, the second insulation layer 106 is a second gate insulation layer, and the second gate insulation layer covers the active layer 103. The second gate insulation layer is mainly configured to isolate the first metal layer 105 from a second metal layer 107.

In an embodiment, the thickness of the second insulation layer 106 is 50 to 200 nm.

In an embodiment, the first gate insulation layer and the second gate insulation layer may be made of silicon nitride, silicon oxide, silicon oxynitride, or the like.

S1026: Form a second metal layer 107 on the second insulation layer 106.

The metal material of the second metal layer 107 is same as the metal material of the first metal layer 105, and may be usually metal such as molybdenum, aluminum, aluminum nickel alloy, molybdenum tungsten alloy, chromium, or copper, or may be a composition of several of the foregoing metal materials.

In an embodiment, the metal material of the second metal layer 107 may be molybdenum.

In an embodiment, the thickness of the second metal layer 107 is 150 to 250 nm.

In this step, a third mask manufacturing process is used for a metal layer for forming the second metal layer 107, and after a third photoresist layer is formed on the metal layer, exposed using a mask plate (not drawn), developed, and treated using a third etching patterning process, the metal layer forms the second metal layer 107 of the array substrate.

In an embodiment, the area of the second metal layer 107 is greater than the area of the first metal layer 105. An orthographic projection of the first metal layer 105 on the second metal layer 107 falls within the second metal layer 107.

S1027: Form the third insulation layer 108 on the second metal layer 107.

In this step, the third insulation layer 108 is an inter-layer insulation layer, and the inter-layer insulation layer covers the second metal layer 107. The inter-layer insulation layer is mainly configured to isolate the second metal layer 107 from a source and drain 112.

In an embodiment, the thickness of the inter-layer insulation layer is 50 to 200 nm.

S103: Perform ion doping on a part of the active layer 103, so that the part of the active layer 103 forms a first doped region 109 and a second doped region 110.

As shown in FIG. 2B to FIG. 2D, step S103 specifically includes the following steps.

S10311: Perform ion doping on the part of the active layer 103 by using the second metal layer 107 and the first metal layer 105 as blocking layers, so that the part of the active layer 103 forms the first doped region 109.

Referring to FIG. 2B, in this step, the second metal layer 107 and the first metal layer 105 are mainly used as blocking layers, and ion injection is performed on the active layer 103. Ion doping enables the part of the active layer 103 to form the first doped region 109.

In an embodiment, doped ions have a high concentration P+, so that the first doped region 109 is also referred to as a heavily doped region.

S10312: Treat the first doped region 109 by using the predetermined process, so that some ions of the first doped region 109 diffuse in all directions from the first doped region 109, and the part of the active layer 103 forms the second doped region 110.

Referring to FIG. 2C, in this step, the first doped region 109 is mainly treated by using the predetermined process, and the predetermined process is a high temperature activation and hydrogenation process, so that some ions of the first doped region 109 diffuse in all directions from the first doped region 109, and the part of the active layer 103 forms the second doped region 110.

In an embodiment, an ion concentration of the first doped region 109 is greater than an ion concentration of the second doped region 110.

Referring to FIG. 2D, a via 111 is formed on a surface of the third insulation layer 108, so that the subsequently formed source and drain 112 is connected to the first doped region 109.

In an embodiment, ion doping needs to be performed using the first metal layer and the second metal layer as blocking layers, so as to form a lightly doped region and a heavily doped region different from each other. Therefore, the area of the first metal layer and that of the second metal layer are inconsistent and have a difference.

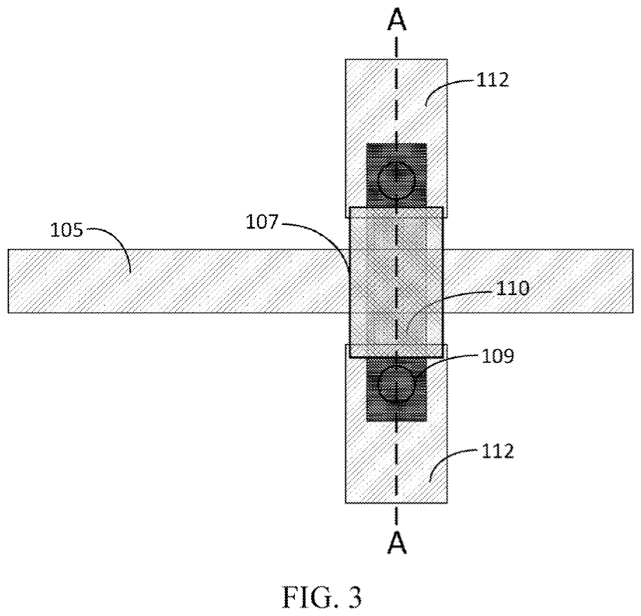

FIG. 3 is a first top view of an array substrate according to Embodiment 1 of the present disclosure. FIG. 2D is a cross-sectional view of a cross section AA in FIG. 3.

Firstly, first time of ion doping is performed on the active layer 103 using the first metal layer 105 as a first blocking layer. Secondly, second time of ion doping is performed on the active layer 103 using the second metal layer 107 as a second blocking layer, that is, a pattern shown in FIG. 2D is formed.

In the present embodiment, the second time of ion doping may be further performed on the active layer 103 using the via 111. By adjusting the concentration of doped ions, the area of the second doped region achieves the pattern shown in FIG. 2D.

As shown in FIG. 2E to FIG. 2G, step S103 may further include the following steps.

S10321: Form a via 111 on the third insulation layer 108.

Referring to FIG. 2E, in this step, the via 111 is formed on a surface of the third insulation layer 108. The via 111 passes through the third insulation layer 108, the second insulation layer 106, and a part of the first insulation layer 104, so that the part of the active layer 103 is exposed.

In an embodiment, the shape of the via 111 may be a polygon or a circle.

In an embodiment, the via 111 is circular.

S10322: Perform ion doping on the exposed part of the active layer 103, so that the part of the active layer 103 forms the first doped region 109.

Referring to FIG. 2F, this step mainly includes performing ion injection on the exposed part of the active layer 103, so that the exposed part of the active layer 103 forms the first doped region 109.

In an embodiment, doped ions have a high concentration P+, so that the first doped region 109 may also be referred to as a heavily doped region.

Because ion injection is performed on only the active layer 103 corresponding to the via 111, the shape of the first doped region 109 is same as the shape of the via 111.

In an embodiment, the shape of the first doped region 109 is a polygon or a circle.

In an embodiment, the shape of the first doped region 109 is a circle.

When an injection amount of boron ions exceeds a value, and boron ions included in the part of the active layer 103 corresponding to the via 111 reach a threshold, boron ions diffuse in all directions.

In an embodiment, a situation in which the shape of the first doped region 109 is different from the shape of the via 111 occurs in diffusion of boron ions.

Boron ions diffuse in all directions, and an ion injection amount is set to not exceed a threshold.

S10323: Treat the first doped region 109 by using the predetermined process, so that some ions of the first doped region 109 diffuse in all directions from the first doped region 109, and the part of the active layer 103 forms the second doped region 110.

Referring to FIG. 2G, in this step, the first doped region 109 is mainly treated by using the predetermined process. The predetermined process is a high temperature activation and hydrogenation process, so that some ions of the first doped region 109 diffuse in all directions from the first doped region 109, and the part of the active layer 103 forms the second doped region 110.

In an embodiment, the ion concentration of the first doped region 109 is greater than the ion concentration of the second doped region 110.

When the via 111 corresponds to an edge of the active layer 103, a pattern shown in FIG. 2G is formed. The area of the second doped region 110 is greater than a difference between the area of the second metal layer 107 and the area of the first metal layer 105.

When a doping amount is increased to a value, for example, exceeds a threshold, the area of the second doped region 110 may be equal to or less than a difference between the area of the second metal layer 107 and the area of the first metal layer 105.

When the via 111 is not located on an edge of the active layer 103, a pattern shown in FIG. 2H is formed. The second doped region 110 surrounds the first doped region 109, and the area of the second doped region 110 is greater than a difference between the area of the second metal layer 107 and the area of the first metal layer 105.

In an embodiment, when an injection amount of ions exceeds a threshold, the pattern shown in FIG. 2G is formed.

Therefore, there may be a plurality of final patterns of the first doped region 109 and the second doped region 110, and patterns of the first doped region 109 and the second doped region 110 are not limited to the two patterns listed in the present embodiment.

In the present disclosure, the first metal layer and the second metal layer different from each other are formed, so that the sizes of the first doped region and the second doped region of the active layer are limited to an extent. However, in actual production, when the second metal layer is not used as a blocking layer, the size of the second metal layer may be same as that of the first metal layer.

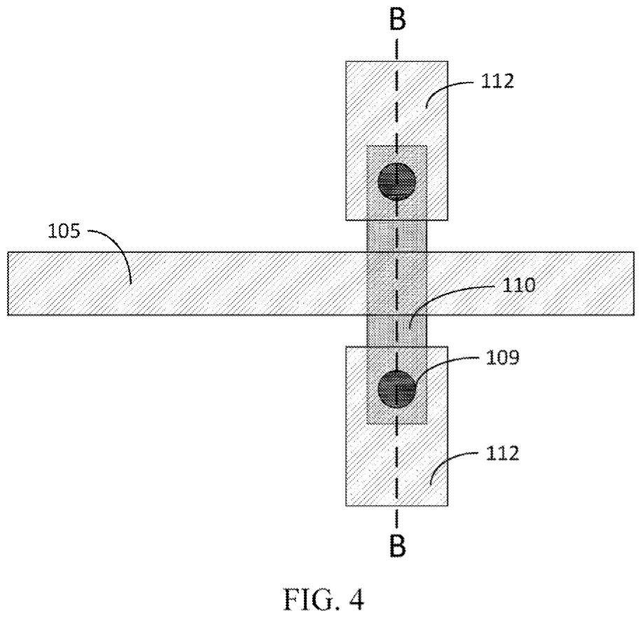

FIG. 4 is a second top view of an array substrate according to Embodiment 1 of the present disclosure. FIG. 2H is a cross-sectional view of a cross section BB in FIG. 4.

A difference between the present embodiment and FIG. 3 is as follows:

In the present embodiment, second time of ion doping is performed without using the second metal layer 107 as a blocking layer, but the second time of ion doping is directly performed on the active layer through the via 111. Therefore, the ion concentration of the second time of ion doping is adjusted, so that the area of the second doped region is same as the embodiment shown in FIG. 2H.

S104: Form a source and drain 112 on the third insulation layer 108.

Referring to FIG. 2I, in this step, the source and drain 112 is formed on the third insulation layer 108. The metal material of the source and drain 112 may be same as the material of the first metal layer 105 and the material of the second metal layer 107, and may be metal such as molybdenum, aluminum, aluminum nickel alloy, molybdenum tungsten alloy, chromium, or copper, or may be a composition of several of the foregoing metal materials.

In an embodiment, the metal material of the source and drain 112 may be titanium aluminum alloy, and the thickness of the source and drain 112 is 400 to 600 nm.

This step includes: using a fourth mask manufacturing process for a metal layer for forming the source and drain 112, forming a fourth photoresist layer on the metal layer, exposing the fourth photoresist layer using a mask plate (not drawn), developing the fourth photoresist layer, and treating the fourth photoresist layer using a fourth etching patterning process; and then forming, by the metal layer, the source and drain 112.

In an embodiment, the source and drain 112 is connected to the first doped region 109 through the via 111.

A planarization layer 113 is formed on the source and drain 112. The planarization layer 113 is configured to ensure flatness of a film layer structure, and form a film layer structure in FIG. 2J or FIG. 2K.

Finally, a process related to an organic light-emitting diode (OLED) or the like is performed.

### Embodiment 2

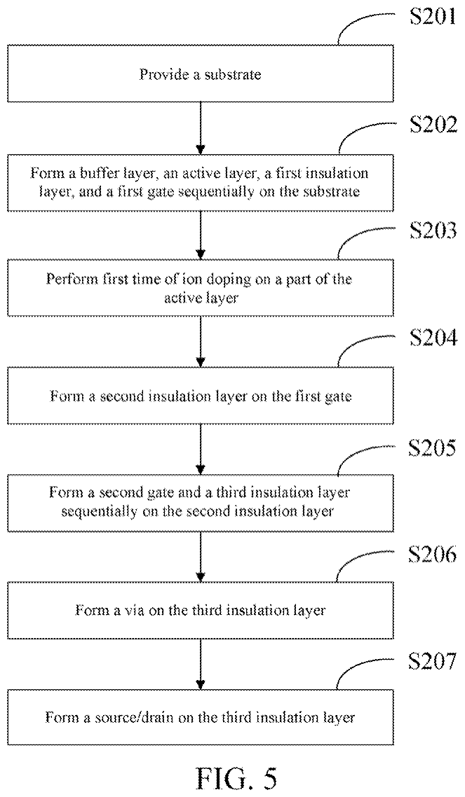

FIG. 5 is a diagram of steps of a manufacturing method for an array substrate according to Embodiment 2 of the present disclosure. The manufacturing method includes the following steps.

S201: Provide a substrate 201.

S202: Form a buffer layer 202, an active layer 203, a first insulation layer 204, and a first metal layer 205 sequentially on the substrate 201.

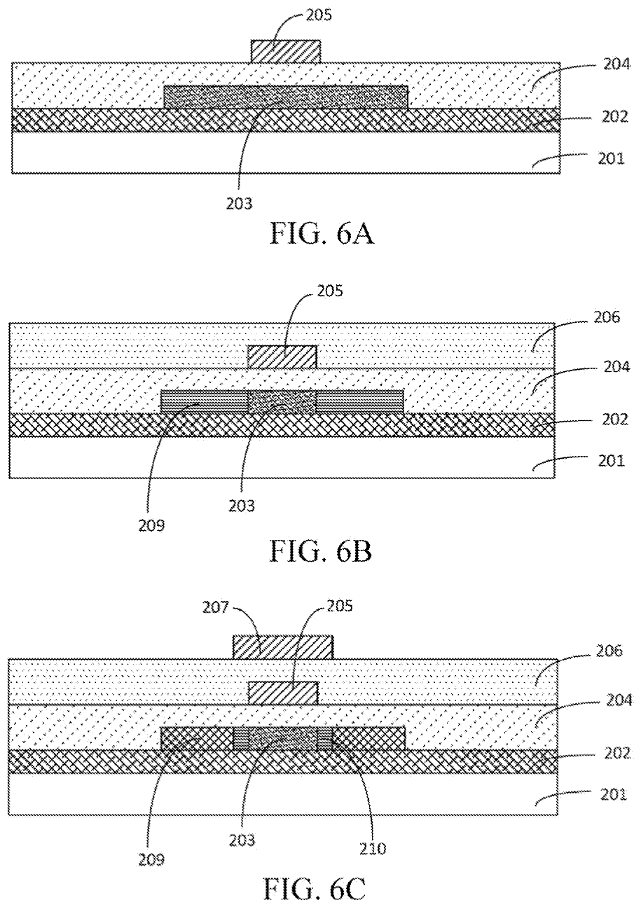

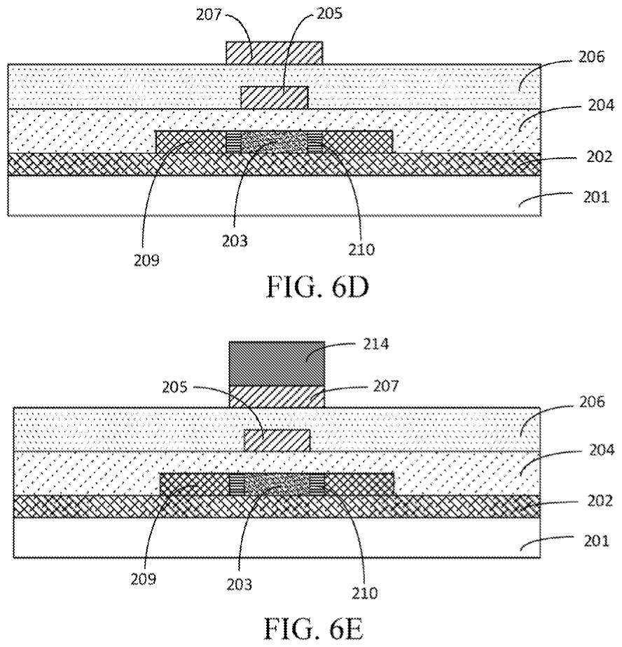

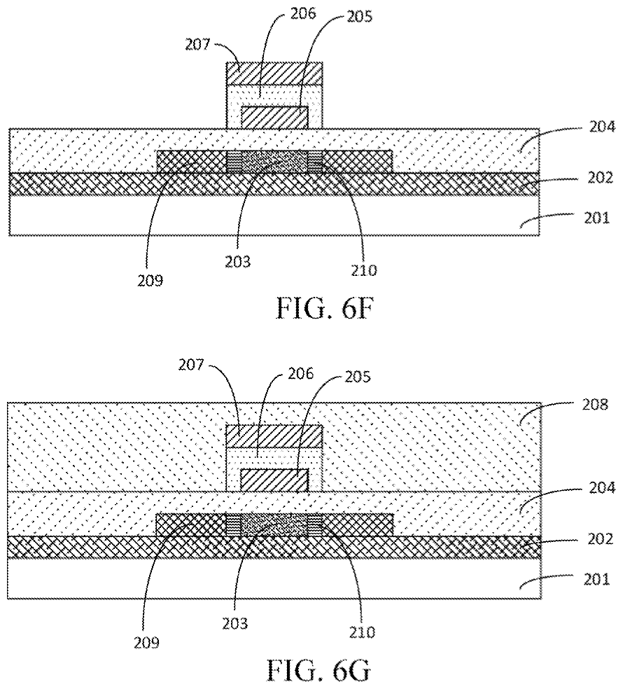

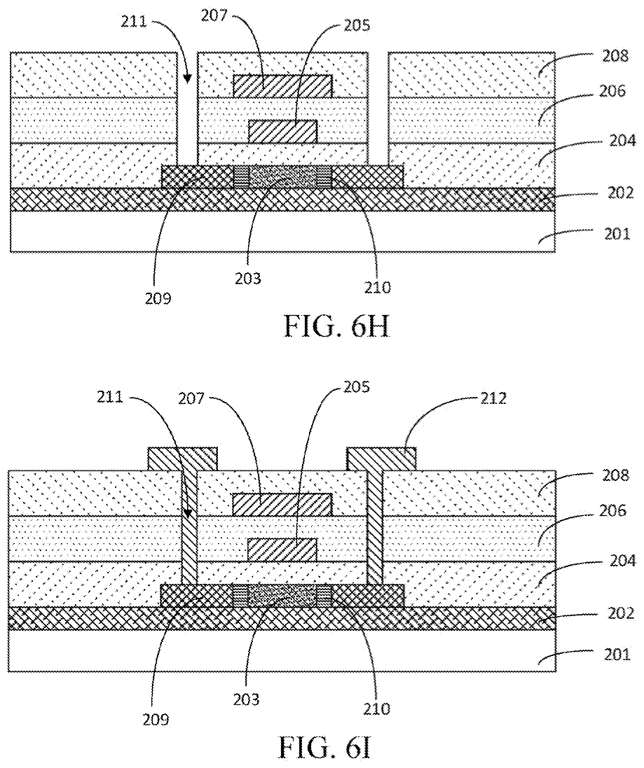

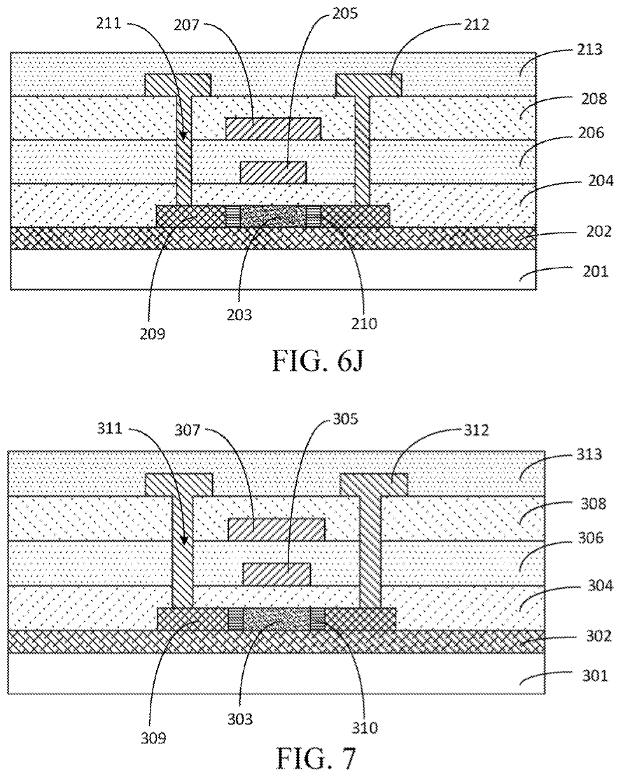

FIG. 6A to FIG. 6J are flowcharts of a manufacturing method for an array substrate according to Embodiment 2 of the present disclosure.

Referring to FIG. 6A, step S201 and step S202 are same as those in specific Embodiment 1, and details are not described again in the present embodiment.

S203: Perform first time of ion doping on a part of the active layer 203, so that the part of the active layer 203 forms a second doped region 210.

Referring to FIG. 6B, this step includes performing first time of ion injection on the active layer 203 using the first metal layer 205 as a blocking layer, to form a doped region.

In an embodiment, doped ions have a high concentration P−, the second doped region 210 may also be referred to as a lightly doped region, and the second doped region 210 is located on two sides of a channel region of the active layer 203.

In an embodiment, a photoresist layer enabling the first metal layer 205 to be patterned and the first metal layer 205 may be both used as blocking layers, and after ion injection is completed, the photoresist layer is stripped.

S204: Form a second insulation layer on the first metal layer 205.

S205: Form a second metal layer 207 and a third insulation layer 208 sequentially on the second insulation layer.

Step S205 mainly includes the following steps.

S20511: Form the second metal layer 207 on the second insulation layer.

S20512: Perform second time of ion doping on the part of the active layer 203 using the second metal layer 207 as a blocking layer, so that the part of the active layer 203 forms a first doped region 209.

Referring to FIG. 6C, this step includes performing ion injection on the part of the active layer 203 using the second metal layer 207 as a blocking layer, so that the part of the active layer 203 forms the first doped region 209.

In an embodiment, doped ions have a high concentration P+, and the first doped region 209 may also be referred to as a heavily doped region.

S20513: Form the third insulation layer 208 on the second metal layer 207.

Referring to FIG. 6D, step S2051 may be also performing ion injection on the part of the active layer 203 after the third insulation layer 208 is formed.

This step may further include the following steps.

S20521: Form the second metal layer 207 on the second insulation layer.

In this step, the step of forming the second metal layer 207 is same as that in specific Embodiment 1, but a photoresist layer 214 enabling the second metal layer 207 to be patterned is reserved.

S20522: Perform second time of ion doping on the part of the active layer 203 using the second metal layer 207 and a photoresist layer 214 enabling the second metal layer 207 to be patterned as blocking layers, so that the part of the active layer 203 forms a first doped region 209.

Referring to FIG. 6E, this step includes performing second time of ion injection on the part of the active layer 203 using the second metal layer 207 and the photoresist layer enabling the second metal layer 207 to be patterned as blocking layers, so that the part of the active layer 203 forms a first doped region 209.

In an embodiment, doped ions have a high concentration P+, and the first doped region 209 may also be referred to as a heavily doped region.

S20523: Form the third insulation layer 208 on the second metal layer 207.

In this step, a pattern shown in FIG. 6D is mainly formed.

This step may further include the following steps.

S20531: Form a second metal layer 207 and a patterned third insulation layer on the second insulation layer.

Referring to FIG. 6F, in this step, both a metal layer for forming the second metal layer 207 and the second insulation layer are patterned, to form the second metal layer 207 and a patterned second insulation layer.

S20532: Perform second time of ion doping on the part of the active layer 203 using the second metal layer 207 and the patterned second insulation layer as blocking layers, so that the part of the active layer 203 forms a first doped region 209.

Referring to FIG. 6F, this step includes performing second time of ion injection on the part of the active layer 203 using the second metal layer 207 and the patterned second insulation layer as blocking layers, so that a part of the second doped region 210 forms a first doped region 209.

In an embodiment, doped ions have a high concentration P+, and the first doped region 209 may also be referred to as a heavily doped region.

S20533: Form the third insulation layer 208 on the second metal layer 207.

Referring to FIG. 6G, in step S2053, the photoresist layer enabling the second metal layer 207 to be patterned may likewise be reserved as a blocking layer, and after second time of ion doping is completed, the photoresist layer is stripped.

In step S205, the first doped region 209 includes boron ions having a high concentration, and the second doped region 210 includes boron ions having a low concentration. Therefore, an ion concentration of the first doped region 209 is greater than an ion concentration of the second doped region 210.

The first doped region 209 and the second doped region 210 may have a plurality of final patterns. This is same as specific Embodiment 1. Ion injection is completed. To control the area of the first doped region 209 and the area of the second doped region 210, the ion concentration of the doped region may be adjusted using a predetermined process.

S206: Form a via 211 on the third insulation layer 208.

Referring to FIG. 6H, the via 211 is formed on a surface of the third insulation layer 208. The via 211 passes through the third insulation layer 208, the second insulation layer 206, and a part of the first insulation layer 204, so that a part of the first doped region 209 is exposed.

S207: Form a source and drain 212 on the third insulation layer 208.

Referring to FIG. 6I, the source and drain 212 is connected to the first doped region 209 through the via 211.

Finally, a planarization layer 213 is formed on the source and drain 212, to ensure flatness of a film layer structure, and form a film layer structure shown in FIG. 6H or FIG. 2K.

Finally, a process related to an OLED or the like is entered.

The present disclosure provides a manufacturing method for an array substrate. In the manufacturing method, ion doping is performed once on the active layer, and the doped active layer forms the first doped region and the second doped region 210 using a predetermined process. In the present disclosure, on the basis of the current process and without increasing the quantity of masks, a PMOS LDD structure is added to an AMOLED. This effectively reduces a period of a panel array manufacturing process and reduces manufacturing costs.

### Embodiment 3

FIG. 7 is a diagram of a first film layer structure of an array substrate according to Embodiment 3 of the present disclosure.

The array substrate includes a substrate 301, a buffer layer, an active layer 303, a first insulation layer 304, a first metal layer 305, a second insulation layer, a second metal layer 307, a third insulation layer 308, a source and a drain 312 and a planarization layer.

The substrate 301 may be one of a glass substrate, a quartz substrate, a resin substrate, and the like.

The buffer layer is formed on the substrate 301, is mainly configured to buffer a pressure between film layer structures, and may further have a function of blocking water and oxygen.

The active layer 303 is formed on the buffer layer, and the active layer 303 includes a first doped region 309 and a second doped region 310 that are doped using ions. The first doped region 309 includes boron ions having a high concentration, and the second doped region 310 includes boron ions having a low concentration.

In an embodiment, an ion concentration of the first doped region 309 is greater than an ion concentration of the second doped region 310.

The first insulation layer 304 is formed on the active layer 303.

In an embodiment, the first insulation layer 304 is a first gate insulation layer, the first gate insulation layer covers the active layer 303, and the first gate insulation layer is mainly configured to isolate the active layer 303 from other metal layers.

The first metal layer 305 is formed on the first insulation layer 304. The metal material of the first metal layer 305 may be usually metal such as molybdenum, aluminum, aluminum nickel alloy, molybdenum tungsten alloy, chromium, or copper, or may be a composition of several of the foregoing metal materials.

The second insulation layer 306 is formed on the first metal layer 305.

In an embodiment, the second insulation layer 306 is a second gate insulation layer, the second gate insulation layer covers the active layer 303, and the second gate insulation layer is mainly configured to isolate the first metal layer 305 from the second metal layer 307.

In an embodiment, the thickness of the second insulation layer 306 is 50 to 200 nm. The material of the second gate insulation layer may be silicon nitride, or may be silicon oxide, silicon oxynitride, or the like.

The second metal layer 307 is formed on the second insulation layer 306, and the material of the second metal layer 307 is same as that of the first metal layer 305.

In an embodiment, the metal material of the first metal layer 305 and the metal material of the second metal layer 307 may be molybdenum.

A metal layer for forming the second metal layer 307 is patterned, to form the second metal layer 307 whose area is greater than that of the first metal layer 305. An orthographic projection of the first metal layer 305 on the second metal layer 307 falls within the second metal layer 307.

The third insulation layer 308 is formed on the second metal layer 307.

In an embodiment, the third insulation layer 308 is an inter-layer insulation layer, the inter-layer insulation layer covers the second metal layer 307, and the inter-layer insulation layer is mainly configured to isolate the second metal layer 307 from the source and drain 312.

In an embodiment, the thickness of the inter-layer insulation layer is 50 to 200 nm.

A via 311 is formed on a surface of the third insulation layer 308. The via 311 passes through the third insulation layer 308, the second insulation layer 306, and a part of the first insulation layer 304.

In an embodiment, the shape of the via 311 may be a polygon or a circle.

In an embodiment, the via 311 is circular.

The source and drain 312 is formed on the third insulation layer 308, and the metal material of the source and drain 312 may be usually metal such as molybdenum, aluminum, aluminum nickel alloy, molybdenum tungsten alloy, chromium, copper or titanium aluminum alloy, or may be a composition of several of the foregoing metal materials.

In an embodiment, the metal material of the source and drain 312 may be titanium aluminum alloy. The source and drain 312 is connected to the first doped region 309 through the via 311.

The planarization layer 313 is formed on the source and drain 312, to ensure flatness of the film layer structure of the array substrate.

In the present embodiment, the foregoing structure is formed mainly by performing ion injection once on the exposed part of the active layer 303 through the via 311, so that the part of the active layer 303 forms the first doped region 309. Doped ions have a high concentration P+, and the first doped region 309 may also be referred to as a heavily doped region.

In an embodiment, the first doped region 309 is treated using the predetermined process, and the predetermined process is a high temperature activation and hydrogenation process, so that some ions of the first doped region 309 diffuse in all directions from the first doped region 309, and the part of the active layer 303 forms the second doped region 310.

Because ion injection is performed on only the active layer 303 corresponding to the via 311, the shape of the first doped region 309 is same as the shape of the via 311, that is, the shape of the first doped region 309 is a polygon or a circle.

In an embodiment, the first doped region 309 is circular.

When an ion injection amount of the first doped region 309 exceeds a threshold, boron ions in the region diffuse in all directions. As a result, the shape of the first doped region 309 is different from the shape of the via 311, and a specific shape is not limited.

Referring to FIG. 7, the via 311 is close to an edge of the active layer 303, that is, the area of the second doped region 310 is equal to a difference between the area of the second metal layer 307 and the area of the first metal layer 305.

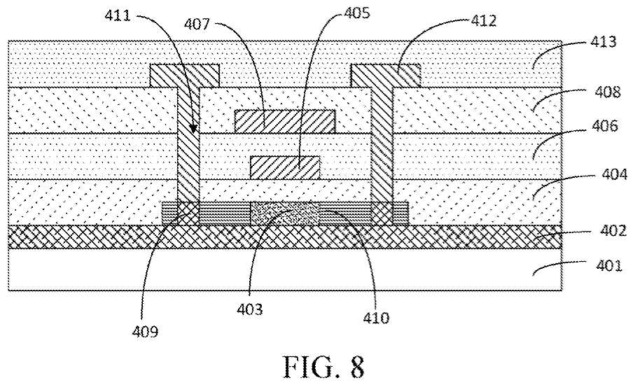

FIG. 8 is a diagram of a second film layer structure of an array substrate according to Embodiment 3 of the present disclosure.

The second doped region 410 surrounds the first doped region 409, and the area of the second doped region 410 is greater than a difference between the area of the second metal layer 407 and the area of the first metal layer 405.

The second doped region 410 is mainly configured to bear a part of a voltage in a circuit, that is, increase in the area of the second doped region 410 may better prevent a thermal electron degeneration effect, and reduce a channel leakage current.

The shape of the first doped region and the shape of the second doped region are related to the ion concentration, the ion injection amount, the shape of the active layer, the process, a human factor and the like. Therefore, the pattern of the first doped region and the pattern of the second doped region are not limited to the shapes shown in FIG. 5 and FIG. 6 in the present disclosure.

The present disclosure further provides a display panel. The display panel includes the foregoing array substrate, the operating principle of the display panel is same as the operating principle of the array substrate, and details are not described herein again.

The present disclosure provides an array substrate, a manufacturing method for same, and a display panel. In the manufacturing method, ion doping is performed once on the active layer, and the doped active layer forms the first doped region and the second doped region using a particular process. In the present disclosure, on the basis of the current process and without increasing the quantity of masks, a PMOS LDD structure is added to an AMOLED. This effectively reduces a period of a panel array manufacturing process and reduces manufacturing costs.

To sum up, although the present disclosure is disclosed above with reference to preferred embodiments, the preferred embodiments are not intended to limit the present disclosure. Those of ordinary skill in the art may make various variations and modifications without departing from the spirit and scope of the present disclosure. Therefore, the protection scope of the present disclosure is subject to the scope defined by the claims.

What is claimed is:

1. A manufacturing method for an array substrate, comprising steps of:
S101: providing a substrate;
S102: forming a buffer layer, an active layer, a first insulation layer, a first metal layer, a second insulation layer, a second metal layer, and a third insulation layer sequentially on the substrate,
wherein an area of the second metal layer is greater than an area of the first metal layer;
S103: performing ion doping on a part of the active layer, so that the part of the active layer forms a first doped region and a second doped region,
wherein the second doped region is formed after the first doped region is formed through a predetermined process; and
S104: forming a source and drain layer on the third insulation layer.

2. The manufacturing method as claimed in claim 1, wherein S103 comprises steps of:
S10311: performing ion doping on the part of the active layer using the second metal layer and the first metal layer as blocking layers, so that the part of the active layer forms the first doped region; and
S10312: treating the first doped region using the predetermined process, so that some ions of the first doped region diffuse in all directions from the first doped region, and the part of the active layer forms the second doped region,
wherein an ion concentration of the first doped region is greater than an ion concentration of the second doped region.

3. The manufacturing method as claimed in claim 1, wherein the second doped region surrounds the first doped region.

4. The manufacturing method as claimed in claim 1, wherein an area of the second doped region is greater than or equal to a difference between the area of the second metal layer and the area of the first metal layer.

5. The manufacturing method as claimed in claim 1, wherein S103 comprises steps of:
S10321: forming a via on the third insulation layer,
wherein the via passes through the third insulation layer, the second insulation layer, and a part of the first insulation layer, so that the part of the active layer is exposed at the via;
S10322: performing ion doping on the exposed part of the active layer, so that the part of the active layer forms the first doped region; and
S10323: treating the first doped region by using the predetermined process, so that some ions of the first doped region diffuse in all directions from the first doped region, and the part of the active layer forms the second doped region.

6. The manufacturing method as claimed in claim 5, wherein the first doped region has a shape same as a shape of the via, and the shape of the first doped region is a polygon or a circle.

7. The manufacturing method as claimed in claim 1, wherein the forming the first doped region and the second doped region comprises steps of:
performing first time of ion doping on the part of the active layer by using the first metal layer as a blocking layer, so that the part of the active layer forms the second doped region; and
performing second time of ion doping on the part of the active layer using the second metal layer as a blocking layer, so that the part of the active layer forms the first doped region.

8. The manufacturing method as claimed in claim 7, wherein the performing second time of ion doping on the part of the active layer using the second metal layer as a blocking layer further comprises a step of:
performing second time of ion doping on the part of the active layer using the second metal layer and a photoresist enabling the second metal layer to be patterned, the second metal layer and the patterned second insulation layer, and the second metal layer, the photoresist enabling the second metal layer to be patterned and the patterned second insulation as blocking layers, so that the part of the active layer forms the first doped region.

9. An array substrate, comprising a substrate, an active layer located on the substrate, a first metal layer located on the active layer, and a second metal layer located on the first metal layer,
wherein the active layer comprises a first doped region and a second doped region, and an area of the second doped region is greater than or equal to a difference between the area of the second metal layer and the area of the first metal layer.

10. The array substrate as claimed in claim 9, wherein the area of the second metal layer is greater than the area of the first metal layer.

11. The array substrate as claimed in claim 9, wherein the array substrate further comprises at least two vias and a source and drain layer; and
the source and drain layer is electrically connected to the second doped region through the vias.

12. The array substrate as claimed in claim 11, wherein the first doped region has a shape same as a shape of the via, and the shape of the first doped region is a polygon or a circle.

13. The array substrate as claimed in claim 9, wherein the second doped region surrounds the first doped region.

14. The array substrate as claimed in claim 9, wherein an ion concentration of the first doped region is greater than an ion concentration of the second doped region.

15. A display panel, wherein the display panel comprises an array substrate, and the array substrate comprises a substrate, an active layer located on the substrate, a first metal layer located on the active layer, and a second metal layer located on the first metal layer,
wherein the active layer comprises a first doped region and a second doped region, and an area of the second doped region is greater than or equal to a difference between the area of the second metal layer and the area of the first metal layer.

16. The display panel as claimed in claim 15, wherein the area of the second metal layer is greater than the area of the first metal layer.

17. The display panel as claimed in claim 15, wherein the array substrate further comprises at least two vias and a source and drain layer; and
the source and drain layer is electrically connected to the second doped region through the vias.

18. The display panel as claimed in claim 17, wherein the first doped region has a shape same as a shape of the via, and the shape of the first doped region is a polygon or a circle.

19. The display panel as claimed in claim 15, wherein the second doped region surrounds the first doped region.

20. The display panel as claimed in claim 15, wherein an ion concentration of the first doped region is greater than an ion concentration of the second doped region.
